(19) United States
(12) Patent Application Publication
(10) Pub. No.: US 2008/0199018 A1
(43) Pub. Date: Aug. 21, 2008

(54) Active earphone with multiple speakers

(75) Inventor: Yi-Rong Chen, Taipei City (TW)

Correspondence Address: BRUCE H. TROXELL, SUITE 1404, 5205 LEESBURG PIKE, FALLS CHURCH, VA, 22041, US

(73) Assignee: IATEC LIMITED

(21) Appl. No.: 11/798,052

(22) Filed: May 9, 2007

(30) Foreign Application Priority Data
Feb. 15, 2007 (TW) 096203015

(51) Int. Cl. H03G 3/00; H04R 5/02

(52) U.S. Cl. 381/61; 381/309

(57) ABSTRACT

An active type earphone with multiple speakers provides filters, amplifiers, a cell and speakers therein to allow the earphone receiving sound track signals individually and dividing the sound track signals into a plurality of band signals. Hence, different band signals are played with the speakers for better stereo sound effect being obtained.

### BACKGROUND OF THE INVENTION

1. Field of the Invention

The present invention is related to an earphone and particularly to an earphone with multi-sound tracks and multi-speakers for obtaining better stereo sound effect.

2. Brief Description of Related Art:

Many earphones have been invented and disclosed such as Taiwan Utility Model Nos. M292862, M271332 and M248180 for improving sound effect.

Wherein, M292862, which is disclosed by the inventor, includes a casing member in associated with a cover member, a first speaker, a second speaker and a mask member. The first speaker, the second speaker and the mask member are joined to inner side and the outer side of the cover member respectively. It is characterized in that the central shafts of the first and second speakers are directed to the lower end of the cover member corresponding to the auditory canal in the ear of the user while the earphone is worn such that sound wave with the largest amplitude sent out via the speakers can be received by the auditory canal for better stereo sound effect.

Referring to FIG. 1, the conventional stereo players 10 such as radio with tape recorder, MP3 player and Video player are electrically connected to the left and right sound track speakers 21, 22 of the muff type earphone such that the left and right sound tracks are capable of outputting to the left and right speakers 21, 22 for the earphone 20 playing the stereo sound.

### SUMMARY OF THE INVENTION

The crux of the present invention is to improve the conventional muff type earphone as an active earphone such that single sound track signal can be divided into a plurality of band signals and a plurality of speakers are capable of playing different band sounds correspondingly for obtaining much better stereo sound effect.

The primary object of the present invention is to provide an active type earphone, which is capable of receiving left and right sound track signals individually and dividing the sound track signals into a plurality of band signals for being played with the speakers as different band sounds to obtain better stereo

### BRIEF DESCRIPTION OF THE DRAWINGS

The present invention can be more fully understood by reference to the following description and accompanying drawings, in which:

FIG. 1 is a block diagram illustrating functional structure of the conventional earphone;

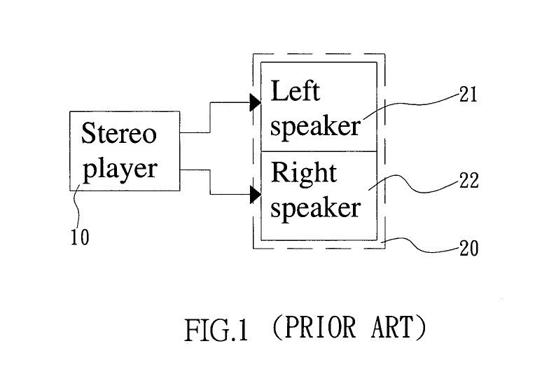

FIG. 2 is a block diagram illustrating functional structure of the first embodiment of an earphone according to the present invention;

FIG. 3 is a curve diagram illustrating sound response with respect to frequency of the first and second filters in the first embodiment of the present invention;

FIG. 4 is a block diagram illustrating functional structure of the second embodiment of an earphone according to the present invention; and

FIG. 5 is a curve diagram illustrating sound response with respect to frequency of the first and second filters in the second embodiment of the present invention.

### DETAILED DESCRIPTION OF THE INVENTION

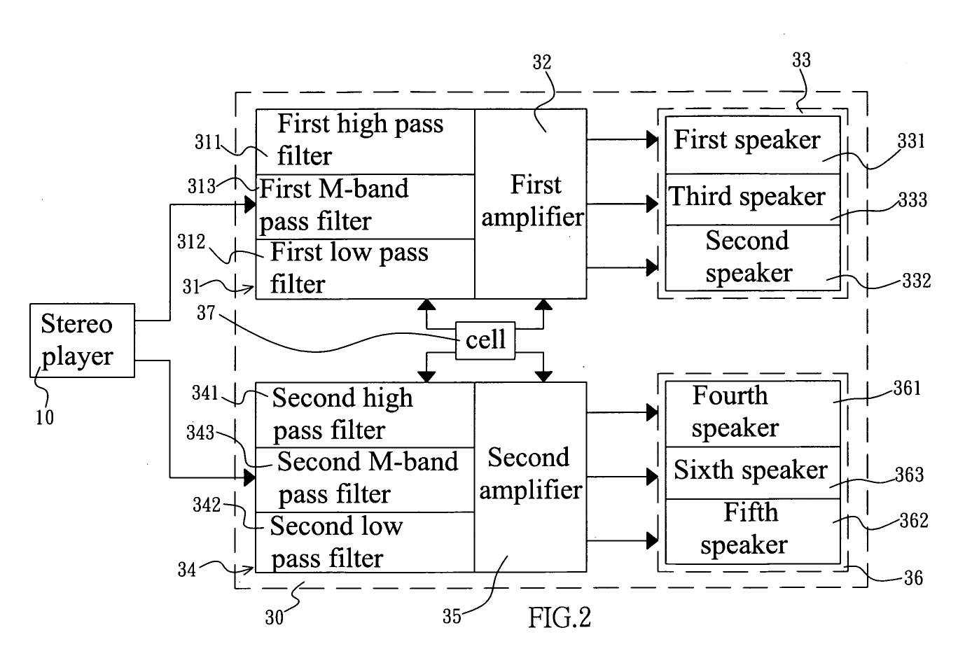

Referring to FIG. 2, the first embodiment of an active type earphone with multiple speakers 30 according to the present invention includes:

a first filter 31, which further includes a first high pass filter 311, a first low pass filter 312 and a first M-band (medium band) pass filter 313;

a first amplifier 32, which is electrically connected to the first filter 31 to amplify output signal of the first filter 31;

a first speaker set 33, which is electrically connected to the first amplifier 32 and further includes a first, a second and a third speakers 331, 332 and 333 wherein the speakers are high tone, low tone and medium tone speakers respectively for receiving the high tone, the low tone and the medium tone signal output via the first high pass filter 311, the first low pass filter 312 and the first M-band pass filter 313 and playing the corresponding high tone, low tone and medium tone respectively;

a second filter 34, which includes a second high pass filter 341, a second low pass filter 342 and a second M-band pass filter 343;

a second amplifier 35, which is electrically connected to the second filter 34 for amplifying output signal of the second filter 34;

a second speaker set 36, which is electrically connected to the second amplifier 32 and further includes a fourth, a fifth and a sixth speakers 361, 362 and 363 wherein the fourth, the fifth and the sixth speakers are high tone, low tone and medium tone speakers respectively for receiving the high tone, the low tone and the medium tone signal output via the second high pass filter 341, the second low pass filter 342 and the second M-band pass filter 343 and playing the corresponding high tone, low tone and medium tone respectively; and

a cell 37, which is electrically connected to the first and second filters 31, 34 and the first and second amplifiers 32, 35 respectively for supplying power needed by the first and second filters 31, 34 and the first and second amplifiers 32, 35 and can be dry cell.

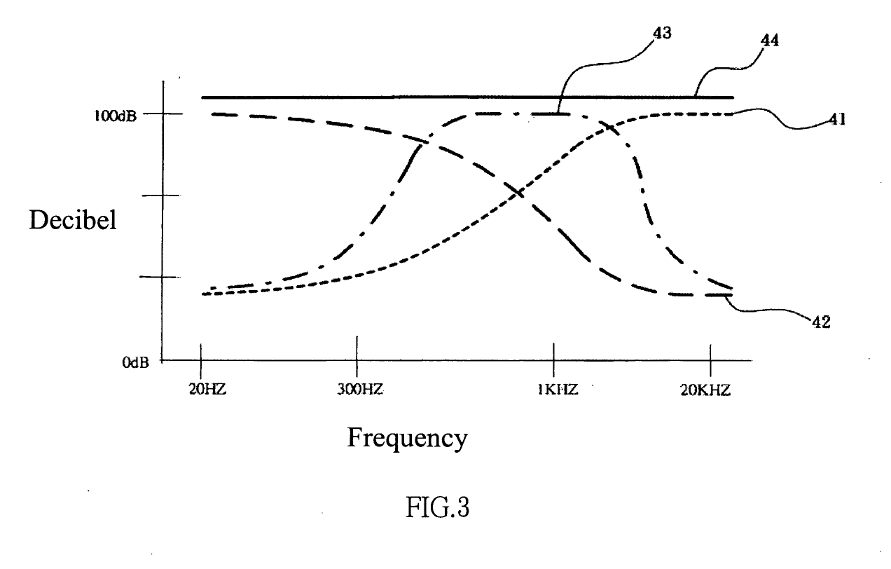

Referring to FIG. 3 in company with FIG. 2, the sound response curves with respect to frequency for the first and second high pass filters 311, 341, the first and second low pass filters 312, 342 and the first and second M-band filters 313, 343 are the first, second and third curves 41, 42 and 43 respectively. It can be seen the final curve 44 synthesized is an ideal frequency response curve for the embodiment illustrated in FIG. 2. The earphone 30 is capable of distinguishing high band signal, low band signal and medium band signal of individual left and right sound tracks output via the stereo player 10. The high band signal, low band signal and the medium band signal are amplified with the first and second amplifiers 32, 35 and sent to the first and the fourth speakers 331, 361, the second and the fifth speakers 332, 362, the third and the sixth speakers 333, 363 to play the high tone, low tone and medium tone. In this way, the earphone 30 provides much better stereo sound effect.

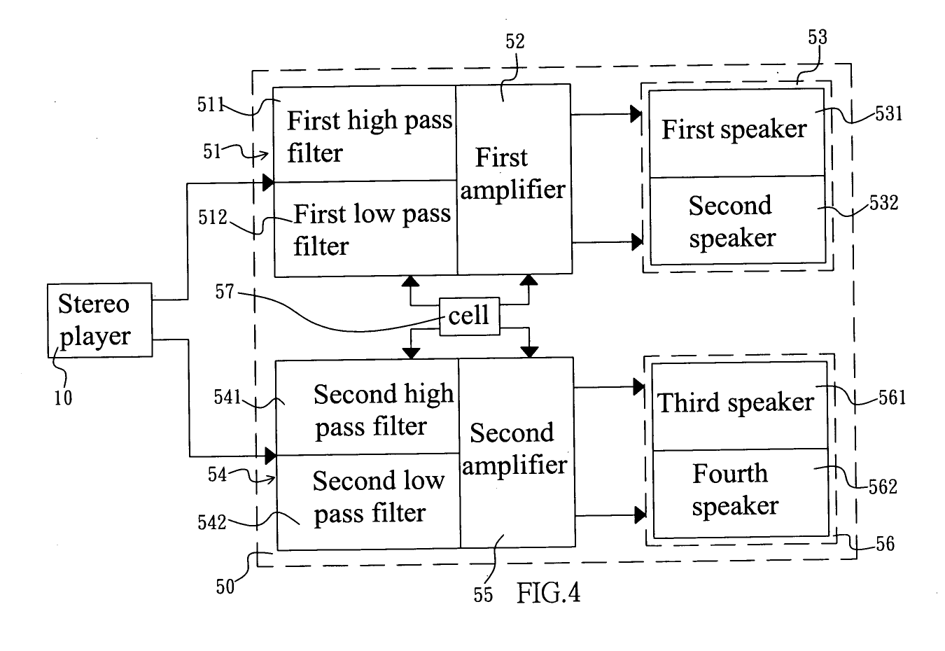

Referring to FIG. 4, the second embodiment of an active type earphone with multiple speakers 50 according to the present invention includes:

a first filter 51, which further includes a first high pass filter 511 and a first low pass filter 512;

a first amplifier 52, which is electrically connected to the first filter 51 to amplify output signal of the first filter 51;

a first speaker set 53, which is electrically connected to the first amplifier 52 and further includes a first and a second speakers 531, 532 wherein the first and second speakers are high tone with medium tone and low tone speakers respectively for receiving the high tone with medium tone signals and the low tone signal output via the first high pass filter 511 and the first low pass filter 512 and playing the corresponding high tone with medium tone and low tone sounds respectively;

a second filter 54, which includes a second high pass filter 541 and a second low pass filter 542;

a second amplifier 55, which is electrically connected to the second filter 54 for amplifying output signal of the second filter 54;

a second speaker set 56, which is electrically connected to the second amplifier 52 and further includes a third and a fourth speakers 561, 562 wherein the third and the fourth speakers are high tone with medium tone and low tone speakers respectively for receiving the high tone with medium tone signals and the low tone signal output via the second high pass filter 541 and the second low pass filter 542 and playing the corresponding high tone with medium tone sounds and low tone sound respectively; and

a cell 57, which is electrically connected to the first and second filters 51, 54 and second amplifiers 52, 55 respectively for supplying power needed by the first and second filters 51, 54 and the first and second amplifiers 52, 55 and can be dry cell.

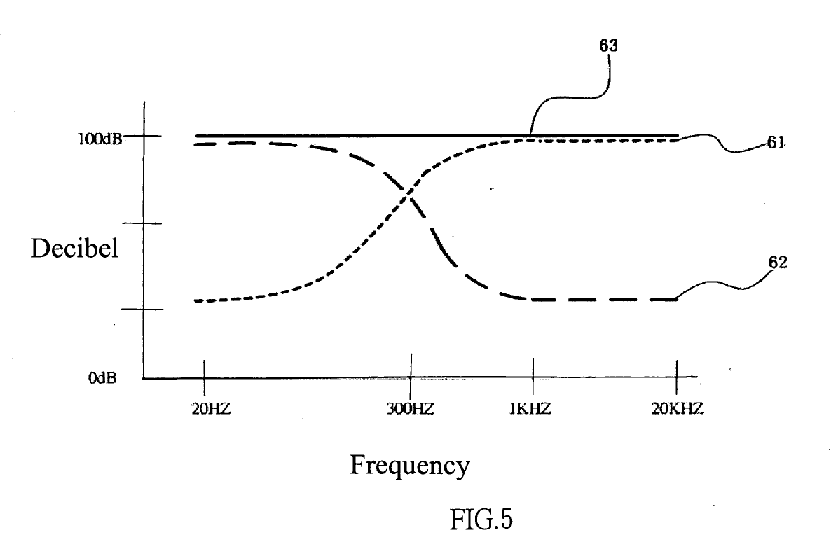

Referring to FIG. 5 in company with FIG. 4, the sound response curves with respect to frequency for the first and second high pass filters 511, 541 and the first and second low pass filters 512, 542 are the first and second curves 61, 62 respectively. It can be seen the final curve 63 synthesized with the first and second curves 61, 62 is an ideal frequency response curve for the embodiment illustrated in FIG. 4. The earphone 50 is capable of distinguishing high band signal with medium signal and low band signal of individual left and right sound tracks output via the stereo player 10. The high band signal with the medium band signal and the low band signal are amplified with the first and second amplifiers 52, 55 and sent to the first and the third speakers 531, 561, the second and the fourth speakers 532, 562 to play the high tone with medium tone sound and the low tone sound. In this way, the earphone 50 provides much better stereo sound effect.

It is noted that the active type earphone with multiple speakers according to the present invention can be muff type earphone with filters, amplifiers, a cell and speakers in the earphone to allow the earphone receiving the left and right sound track signals individually and dividing the sound track signals into a plurality of band signals. Hence, different band signals are played with the speakers such that better stereo sound effect can be obtained with the earphone of the present invention.

While the invention has been described with referencing to preferred embodiments thereof, it is to be understood that modifications or variations may be easily made without departing from the spirit of this invention, which is defined by the appended claims.

What is claimed is:

1. An active type earphone with multiple speakers comprising:
a first filter further comprising a first high pass filter and a first low pass filter;
a first amplifier being electrically connected to the first filter to amplify output signal of the first filter;
a first speaker set being electrically connected to the first amplifier and further comprising a first, a second and a third speakers for receiving signals output via the first high pass filter and the first low pass filter and playing the corresponding sounds respectively; and
a cell being electrically connected to the first filter and the first amplifier respectively for supplying power needed by the first and second filters and the first and second amplifiers.

2. The active type earphone with multiple speakers as defined in claim 1, wherein the first speaker and the second speaker are a medium and high tone speaker and a low tone speaker.

3. The active type earphone with multiple speakers as defined in claim 1, wherein the first filter further comprises a first medium band filter and the first speaker set further comprises a third speaker for receiving output signal of the first medium band filter and playing sound corresponding to the output signal of the first medium band filter.

4. The active type earphone with multiple speakers as defined in claim 3, wherein the first, second and third speakers are high tone, low tone and medium tone speakers.

5. The active type earphone with multiple speakers as defined in claim 1 further comprises:
a second filter comprising a second high pass filter and a second low pass filter;
a second amplifier being electrically connected to the second filter for amplifying output signal of the second filter.
a second speaker set being electrically said second amplifier and further comprising a third speaker and a fourth speaker for receiving output signals of said second high pass filter and said second low pass filter and playing sounds corresponding to the output signals of said second high pass filter and the second low pass filter;
wherein the cell is electrically connected to the second filter and the second amplifier for supplying power needed by said second filter and said second amplifier.

6. The active type earphone with multiple speakers as defined in claim 5, wherein the third speaker and fourth speaker are medium and high tone speaker and low tone speaker respectively.

7. The active type earphone with multiple speakers as defined in claim 3 further comprises:
a second filter comprising a second high pass filter, a second low pass filter and a second medium band filter;
a second amplifier being electrically connected to the second filter for amplifying output signal of the second filter.
a second speaker set being electrically said second amplifier and further comprising a fourth speaker, a fifth speaker and a sixth speaker for receiving output signals of said second high pass filter, said second low pass filter and said second medium band filter and playing sounds corresponding to the output signals of said second high pass filter, the second low pass filter and the second medium band filter;
wherein the cell is electrically connected to the second filter and the second amplifier for supplying power needed by said second filter and said second amplifier.

8. The active type earphone with multiple speakers as defined in claim 7, wherein the fourth, fifth and sixth speakers are high tone, low tone and medium tone speakers.

9. The active type earphone with multiple speakers as defined in claim 7, wherein the earphone is muff type earphone.
